(19) United States
(12) Patent Application Publication
(10) Pub. No.: US 2026/0075799 A1
(43) Pub. Date: Mar. 12, 2026

(54) SEMICONDUCTOR STRUCTURE

(71) Applicant: CXMT Corporation, Hefei City (CN)

(72) Inventors: SHIJIE BAI, Hefei City (CN); Bohui SHENG, Hefei City (CN); Depeng RAO, Hefei City (CN)

(73) Assignee: CXMT Corporation, Hefei City (CN)

(21) Appl. No.: 19/253,113

(22) Filed: Jun. 27, 2025

Related U.S. Application Data
(63) Continuation of application No. PCT/CN2025/087718, filed on Apr. 8, 2025.

(30) Foreign Application Priority Data
Sep. 10, 2024 (CN) 202411267639.6

(51) Int. Cl. H10B 12/00

(52) U.S. Cl. CPC H10B 12/315

(57) ABSTRACT

Embodiments of the present disclosure provide a semiconductor structure, including multiple rows of first word lines and multiple first conductive lines. Each of the first conductive lines is provided in correspondence with and connected to each of the first word lines in odd-numbered rows or even-numbered rows; multiple first conductive contacts are each provided in correspondence with each of the first conductive lines, and multiple second conductive contacts are each provided in correspondence with and isolated from each of the first conductive contacts; and each of the second conductive contacts is connected to each of the first contact pads. The semiconductor structure in the embodiments of the present disclosure has a simpler interconnection manner, which simplifies a process flow while increasing signal density.

### CROSS-REFERENCE TO RELATED APPLICATIONS

This application is a continuation of International Patent Application No. PCT/CN2025/087718 filed on Apr. 8, 2025, which claims priority to Chinese Patent Application No. 202411267639.6 filed on Sep. 10, 2024. The disclosures of the above-referenced applications are hereby incorporated by reference in their entirety.

### BACKGROUND

A memory is adopted to store data in modern computing architectures. A dynamic random access memory (DRAM) has advantages of a simple structure, low costs, a high speed, and the like, and is widely adopted as a main memory in personal computers, servers, and various electronic devices.

As data continues to grow rapidly, the density improvement of a DRAM is slowing down, resulting in a growing gap between memory demand and a DRAM capacity. Therefore, it has become an important objective in integrated circuit manufacturing at a current stage to improve a degree of integration by increasing encapsulation density and in turn obtain a higher storage capacity, and a memory with tight encapsulation is urgently to be developed.

### SUMMARY

Embodiments of the present disclosure provide a semiconductor structure with a higher degree of integration.

Embodiments of the present disclosure relate to the field of semiconductor technologies, and in particular, to a semiconductor structure.

The problems to be solved by technical spirits of the present disclosure are not limited to the problem mentioned above, and other problems not mentioned will be clearly understood by a person skilled in the art from the following description.

An example implementation of the present disclosure provides a semiconductor structure. The semiconductor structure includes: a first memory cell array, the first memory cell array including multiple rows of first word lines extending in a first direction, and the first word lines being isolated from each other; a first interconnection region including multiple first conductive lines extending in the first direction, each of the first conductive lines being provided in correspondence with and connected to each of the first word lines in odd-numbered rows or even-numbered rows; a first conductive contact combination, the first conductive contact combination being disposed in the first interconnection region, the first conductive contact combination including multiple first conductive contacts, each of the first conductive contacts being provided in correspondence with each of the first conductive lines, and each of the first conductive contacts extending in a second direction and being connected to each of the first conductive lines; and a second interconnection region, the second interconnection region being disposed adjacent to the first memory cell array and the first interconnection region in the first direction, a second conductive contact combination being provided in the second interconnection region, the second conductive contact combination including multiple second conductive contacts, and each of the second conductive contacts being provided in correspondence with and isolated from each of the first conductive contacts; and multiple first contact pads being provided in the second interconnection region, each of the second conductive contacts extending in the second direction and being connected to each of the first contact pads, where there is a minimum distance D0 between adjacent first conductive contacts in the first direction, there is a minimum distance D1 between adjacent second conductive contacts in the first direction, and the minimum distance D0 is less than the minimum distance D1; and in the second direction, each of the first conductive contacts has a minimum length L0, each of the second conductive contacts has a minimum length L1, and the minimum length L0 is less than the minimum length L1.

In the semiconductor structure provided in the embodiments of the present disclosure, the first conductive contacts are provided in the first interconnection region at a relatively small distance, and the second conductive contacts are provided in the second interconnection region at a relatively large distance. In this way, on the basis of ensuring good isolation between adjacent conductive contacts, a simpler interconnection manner may be provided in the second interconnection region. For example, a single contact pad is provided to be connected to the second conductive contacts to achieve signal transmission in the second interconnection region, thereby simplifying a process flow while increasing signal density.

### BRIEF DESCRIPTION OF DRAWINGS

The accompanying drawings herein, which are incorporated in and constitute a part of the specification, illustrate embodiments consistent with the embodiments of the present disclosure, and serve to explain the principles of the embodiments of the present disclosure together with the specification.

FIG. 1A is a simplified schematic plan view of a semiconductor structure according to an embodiment of the present disclosure;

FIG. 1B is a cross-sectional view of a semiconductor structure according to an embodiment of the present disclosure;

FIG. 2 is a simplified schematic plan view of a semiconductor structure according to an embodiment of the present disclosure;

FIG. 3 is a simplified schematic plan view of a semiconductor structure according to an embodiment of the present disclosure;

FIG. 4A is a simplified schematic plan view of a semiconductor structure according to an embodiment of the present disclosure;

FIG. 4B is a cross-sectional view of a semiconductor structure according to an embodiment of the present disclosure;

FIG. 5 is a simplified schematic plan view of a semiconductor structure according to an embodiment of the present disclosure;

FIG. 6 is a simplified schematic plan view of a semiconductor structure according to an embodiment of the present disclosure;

FIG. 7A is a cross-sectional view of a semiconductor structure according to an embodiment of the present disclosure;

FIG. 7B is a cross-sectional view of a semiconductor structure according to an embodiment of the present disclosure;

The accompanying drawings have already shown clear embodiments of the present disclosure, which are described in more detail below. These accompanying drawings and text descriptions are not intended to limit the scope of the concept of the embodiments of the present disclosure in any manner, but to describe the concept of the embodiments of the present disclosure for a person skilled in the art with reference to specific embodiments.

### DETAILED DESCRIPTION

The technical solutions in the embodiments of the present disclosure are clearly described below with reference to the accompanying drawings in the embodiments of the present disclosure. It may be understood that specific embodiments described herein are merely intended to explain related disclosures, but are not intended to limit the present disclosure. In addition, it should be further noted that for ease of description, only related parts are shown in the accompanying drawings. Unless otherwise defined, all technical and scientific terms employed in this specification have meanings the same as those commonly understood by a person skilled in the technical field of the present disclosure. The terms employed in this specification are merely intended to describe the embodiments of the present disclosure, but are not intended to limit the present disclosure. “Some embodiments” describing a subset of all possible embodiments is involved in the following descriptions. However, it may be understood that “some embodiments” may be the same subset or different subsets of all the possible embodiments, and may be combined with each other when there is no conflict. It should be noted that the term “first/second/third” in the embodiments of the present disclosure is merely intended to distinguish between similar objects, and does not represent specific sorting for the objects. It may be understood that “first/second/third” may be interchanged for a specific sequence or order if allowed, so that the embodiments of the present disclosure described herein can be implemented in a sequence other than those shown or described.

The following describes the embodiments of the present disclosure in detail with reference to the accompanying drawings.

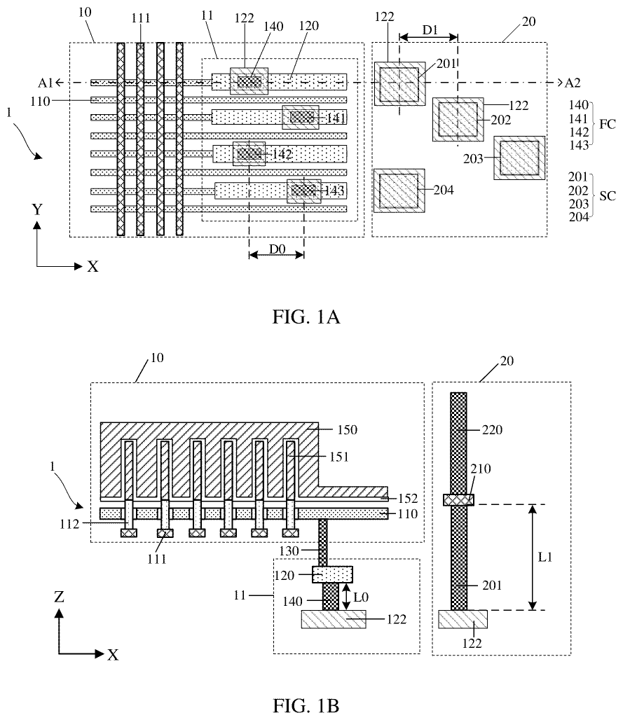

FIG. 1A is a simplified schematic plan view of a semiconductor structure 1 according to an embodiment of the present disclosure. FIG. 1B is a cross-sectional view taken along a line A1-A2 in FIG. 1A. With reference to FIG. 1A and FIG. 1B, the semiconductor structure 1 includes a first memory cell array 10. Multiple rows of word lines disposed in parallel with each other, e.g., multiple rows of first word lines 110 extending in a first direction X, are provided in the first memory cell array 10. The first word lines 110 are parallel to and isolated from each other. The semiconductor structure 1 further includes a first interconnection region 11, and multiple conductive lines extending in the first direction X, e.g., first conductive lines 120, are provided in the first interconnection region 11. The first conductive lines 120 are parallel to each other in the first direction X, and are connected to and provided in correspondence with the first word lines 110 in odd-numbered rows or the first word lines 110 in even-numbered rows respectively. That is, another row of first word lines 110 that is not connected to the first conductive lines 120 is further provided between the first conductive lines 120. The first conductive lines 120 may also be connected to the first word lines 110 respectively. FIG. 1A shows an example in which each of the first conductive lines 120 is connected to each of the first word lines 110 in odd-numbered rows or even-numbered rows. It should be noted that each of the first word lines not connected to each of the first conductive lines 120 is connected to a conductive line disposed in another interconnection region. A first conductive contact combination FC is disposed in the first interconnection region 11, and the first conductive contact combination FC includes a combination of multiple conductive contacts that are provided in correspondence with the first conductive lines 120, e.g., a combination including a first conductive contact 140, a first conductive contact 141, a first conductive contact 142, a first conductive contact 143, and the like. These conductive contacts employ different reference numerals to indicate that the conductive contacts are connected to different first conductive lines 120 respectively.

In the first direction X, there is a distance between adjacent first conductive contacts. For example, there is a distance between the first conductive contact 140 and the first conductive contact 141, there is a distance between the first conductive contact 141 and the first conductive contact 142, and there is also a distance between the first conductive contact 142 and the first conductive contact 143. Distances between adjacent first conductive contacts may be approximately the same or different, and there is a minimum distance, e.g., a minimum distance D0. FIG. 1A illustrates that there is a minimum distance D0 between the first conductive contact 142 and the first conductive contact 143, but the minimum distance D0 may alternatively be a distance between other adjacent first conductive contacts. The value of the minimum distance D0 is greater than 0 and less than the length of extension of each of the first conductive lines 120 in the first direction X. A distance between the first conductive contacts refers to a distance between centers of the first conductive contacts, or may refer to a distance between the same edges of the first conductive contacts or a distance between opposite edges of adjacent first conductive contacts.

The semiconductor structure 1 includes a second interconnection region 20. The second interconnection region 20 is disposed adjacent to the first memory cell array 10 and the first interconnection region 11 in the first direction X, and a second conductive contact combination SC is provided in the second interconnection region 20. The second conductive contact combination SC includes multiple second conductive contacts provided in correspondence with the first conductive contacts, such as a second conductive contact 201 provided in correspondence with the first conductive contact 140, a second conductive contact 202 provided in correspondence with the first conductive contact 141, a second conductive contact 203 provided in correspondence with the first conductive contact 142, and a second conductive contact 204 provided in correspondence with the first conductive contact 143. The second conductive contacts are isolated from each other via a dielectric layer (not shown in the figure).

In the first direction X, adjacent second conductive contacts are spaced apart. For example, there is a distance between the second conductive contact 201 and the second conductive contact 202, there is a distance between the second conductive contact 202 and the third conductive contact 203, and there is also a distance between the second conductive contact 203 and the second conductive contact 204. Distances between adjacent second conductive contacts may be approximately the same or different, and there is a minimum distance, e.g., a minimum distance D1. For example, FIG. 1A illustrates that there is a minimum distance D1 between the second conductive contact 201 and the second conductive contact 202, but the minimum distance D1 may alternatively be a distance between other adjacent second conductive contacts. The value of the minimum distance D1 is greater than 0 and less than the length of extension of the second interconnection region 20 in the first direction X. A distance between the second conductive contacts refers to a distance between centers of the second conductive contacts, or may refer to a distance between the same edges of the second conductive contacts or a distance between opposite edges of adjacent second conductive contacts. The minimum distance D0 between the first conductive contacts is less than the minimum distance D1 between the second conductive contacts.

With continued reference to FIG. 1A and FIG. 1B, multiple first contact pads 210 are further provided in the second interconnection region 20, and each of the second conductive contacts extends in a second direction Z to be connected to a corresponding first contact pad 210. Each of the second conductive contacts has a corresponding length in the second direction Z, the lengths of the second conductive contacts may be approximately the same or different, and there is a minimum length. For example, the second conductive contact 201 has a minimum length L1.

Each of the first conductive contacts extends in the second direction Z to be connected to a first conductive line 120 corresponding thereto. The second direction Z and the first direction X are perpendicular to each other. Each of the first conductive contacts has a corresponding length in the second direction Z, the lengths of the first conductive contacts may be approximately the same or different, and there is a minimum length. For example, the first conductive contact 140 has a minimum length L0. Each of the second conductive contacts extends in the second direction Z to be connected to a first contact pad 210 corresponding thereto, and the minimum length L0 is less than the minimum length L1.

In the above embodiment, the first conductive contacts in the first conductive contact combination FC are disposed in the first interconnection region 11 at a relatively small distance, and the second conductive contacts in the second conductive contact combination SC are disposed in the second interconnection region 20 at a relatively large distance. On the basis of ensuring good isolation between adjacent conductive contacts, a simpler interconnection manner may be provided in the second interconnection region 20. For example, a single contact pad 210 is provided to be connected to the second conductive contacts to achieve signal transmission in the second interconnection region 20, thereby simplifying a process flow while increasing signal density.

The first interconnection region 11 may be located above or below the first memory cell array 10. In some embodiments, the first interconnection region 11 is located above or below an edge portion of the first memory cell array 10, that is, the first interconnection region 11 is a region corresponding to ends of the first word lines 110. A total quantity of rows of the first word lines 110 in the first memory cell array 10 may be an even number, e.g., 512 rows, 1024 rows, or more.

In the second direction Z, a projection of each of the first conductive lines 120 partially overlaps with a projection of each of the first word lines 110 connected correspondingly to each of the first conductive lines 120, and the projection of the first word line 110 is located within the projection of the first conductive line 120. In the second direction Z, a projection of each of the second conductive contacts overlaps with a projection of each of the first contact pads 210 connected correspondingly to each of the second conductive contacts, and the projection of the second conductive contact is located within the projection of the first contact pad 210.

With continued reference to FIG. 1B, in the second direction Z, each of the first conductive lines 120 is connected to each of the first word lines 110 corresponding thereto through a contact plug 130, forming a connection channel between each of the first conductive lines 120 and each of the first word lines 110. A contact plug 220 is further provided on each of the first contact pads 210, forming a channel connected to the first contact pad 210 in a direction away from the second conductive contact combination SC.

With continued reference to FIG. 1A and FIG. 1B, multiple columns of first bit lines 111 are further provided in the first memory cell array 10, and the columns of first bit lines 111 extend and are arranged in a third direction Y, and are spaced apart from each other in the first direction X, and the first direction X and the third direction Y are perpendicular to each other; each column of first bit line 111 extends in the second direction Z, and the extension length of each column of first bit line 111 does not exceed the extension length of each of the contact plugs 130 in the second direction Z; and the second direction Z and the third direction Y are perpendicular to each other. The multiple columns of first bit lines 111 and the multiple rows of first word lines 110 are perpendicular to each other or have a specific included angle therebetween. FIG. 1A shows an example in which the first bit lines 111 and the first word lines are perpendicular to each other, but is not limited thereto. In some embodiments, the first bit lines 111 are disposed closer to the first conductive contact combination FC than the first word lines 110. A total quantity of columns of the first bit lines 111 in the first memory cell array 10 may be an even number, e.g., 512 columns, 1024 columns, or more.

With continued reference to FIG. 1B, multiple active regions 112 that are spaced apart and extend in the second direction Z are further provided in the first memory cell array 10. An end of each of the active regions 112 in the second direction Z is connected to each column of first bit line 111, the other end of each of the active regions 112 in the second direction Z is connected to a capacitor array. The capacitor array includes a bottom electrode 151, a top electrode 150, and a dielectric layer 152 disposed between the top electrode and the bottom electrode, and is configured to store charges. In another embodiment, the capacitor array may alternatively be another type of capacitor storage array. Each row of first word line 110 simultaneously surround portions of sidewalls of the multiple active regions 112 in the first direction X, thereby forming a memory that implements data reading and storage by means of storage and detection of charges in the capacitor array, e.g., a DRAM memory employing a vertical channel transistor (Vertical Channel Transistor). The first conductive contact combination FC is connected to the first word lines 110, and is configured to control opening and closing of an electron flow channel in an active region 112 between each column of first bit line 111 and the capacitor array. The second conductive contact combination SC is connected to the first contact pads 210, and is configured to transmit a current signal in the second interconnection region 20.

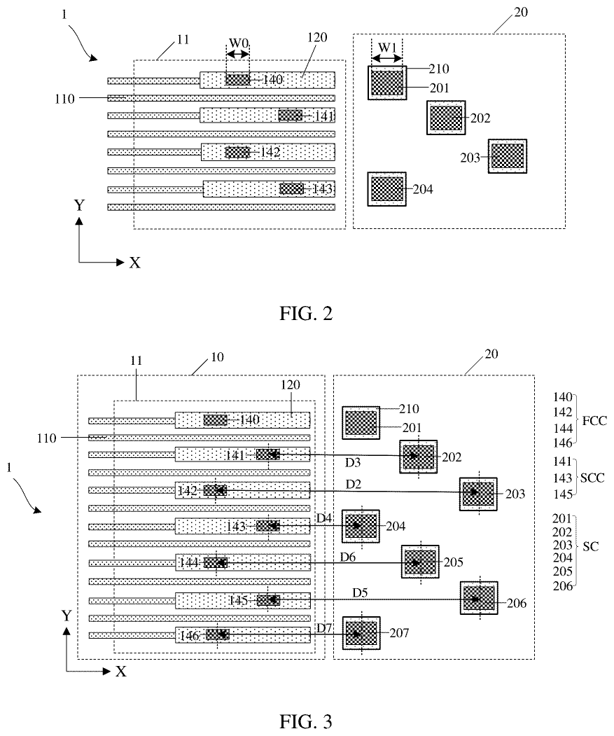

In some embodiments of the present disclosure, as shown in FIG. 2, FIG. 2 is a simplified schematic plan view of the semiconductor structure 1. The first conductive contacts in the semiconductor structure 1 have corresponding widths in the first direction X, the widths of the first conductive contacts may be approximately the same or different, and the first conductive contacts have an average width, e.g., W0. The second conductive contacts also have corresponding widths in the first direction X, the widths of the second conductive contacts may be approximately the same or different, and the second conductive contacts have an average width, e.g., W1. The average width W0 of the first conductive contacts is less than the average width W1 of the second conductive contacts.

Referring to FIG. 1A, FIG. 1B, FIG. 2, and FIG. 3, FIG. 3 is a simplified schematic plan view of the semiconductor structure 1. In some embodiments of the present disclosure, the first conductive contact combination FC further includes a first conductive contact 144, a first conductive contact 145, and a first conductive contact 146, and the second conductive contact combination SC further includes a second conductive contact 205, a second conductive contact 206, and a second conductive contact 207. The first conductive contact combination FC further includes more first conductive contacts, the second conductive contact combination SC further includes more second conductive contacts, and quantities of first conductive contacts and second conductive contacts are not limited to the quantities shown in the accompanying drawings. The first conductive contacts in the first conductive contact combination FC may be classified into a first column of first conductive contact combination FCC and a second column of first conductive contact combination SCC according to an arrangement manner. The first column of first conductive contact combination FCC includes multiple first conductive contacts arranged in the third direction Y. The first conductive contacts in the first column of first conductive contact combination FCC are correspondingly connected to the first conductive lines 120 in odd-numbered rows respectively, such as the first conductive contact 140, the first conductive contact 142, the first conductive contact 144, and the first conductive contact 146. The second column of first conductive contact combination SCC includes multiple first conductive contacts arranged in the third direction Y. The first conductive contacts in the second column of first conductive contact combination SCC are correspondingly connected to the first conductive lines 120 in even-numbered rows respectively, such as the first conductive contact 141, the first conductive contact 143, and the first conductive contact 145. The first conductive contacts in the first column of first conductive contact combination FCC and the first conductive contacts in the second column of first conductive contact combination SCC are arranged in a staggered manner in the first direction X, and have a minimum distance D0 therebetween.

With continued reference to FIG. 3, in some embodiments, the first column of first conductive contact combination FCC includes at least one first conductive contact at a maximum distance from a second conductive contact corresponding thereto. For example, there is a maximum distance D2 between the first conductive contact 142 and the second conductive contact 203; and a combination of the first conductive contact 142, the second conductive contact 203, and a space region between the first conductive contact 142 and the second conductive contact 203 is considered as a first baseline row. In this case, two first conductive contacts 141 and 143 in the second column of first conductive contact combination SCC are provided on two sides adjacent to the first baseline row respectively. There is a maximum distance between the first conductive contact 141 and the second conductive contact 202 corresponding thereto, there is a maximum distance between the first conductive contact 143 and the second conductive contact 204 corresponding thereto, and the two maximum distances are both less than the maximum distance D2.

In some embodiments, the first conductive contacts and the second conductive contacts disposed adjacent to the first baseline row form a first reference row and a second reference row respectively. For example, as shown in FIG. 3, the first conductive contact 141 and the second conductive contact 202 form a first reference row, and the first conductive contact 143 and the second conductive contact 204 form a second reference row; and there is a maximum distance D3 between the first conductive contact and the second conductive contact in the first reference row, and there is a maximum distance D4 between the first conductive contact and the second conductive contact in the second reference row, where D3 is greater than D4, and D3 and D4 are both less than D2.

With continued reference to FIG. 3, in some embodiments, the second column of first conductive contact combination SCC includes at least one first conductive contact at a maximum distance from a second conductive contact corresponding thereto. For example, there is a maximum distance D5 between the first conductive contact 145 and the second conductive contact 206; and a combination of the first conductive contact 145, the second conductive contact 206, and a space region between the first conductive contact 145 and the second conductive contact 206 is considered as a second baseline row. In this case, two first conductive contacts 144 and 146 in the first column of first conductive contact combination FCC are provided on two sides adjacent to the second baseline row respectively. There is a maximum distance between the first conductive contact 144 and the second conductive contact 205 corresponding thereto, there is a maximum distance between the first conductive contact 146 and the second conductive contact 207 corresponding thereto, and the two maximum distances are both less than the maximum distance D5.

In some embodiments, the first conductive contacts and the second conductive contacts disposed adjacent to the second baseline row form a third reference row and a fourth reference row respectively. For example, as shown in FIG. 3, the first conductive contact 144 and the second conductive contact 205 form a third reference row, and the first conductive contact 146 and the second conductive contact 207 form a fourth reference row; and there is a maximum distance D6 between the first conductive contact and the second conductive contact in the third reference row, and there is a maximum distance D7 between the first conductive contact and the second conductive contact in the fourth reference row, where D6 is greater than D7, and D6 and D7 are both less than D5.

The first baseline row, the second baseline row, and the reference rows in the above embodiment refer to virtual rows formed by a set of first conductive contact and second conductive contact corresponding to each other in the first direction X, and are configured to mark positions of the first conductive contact and the second conductive contact corresponding to each other.

In the above embodiment, when the conductive contacts in the first interconnection region 11 and the second interconnection region 20 are arranged, the first column of first conductive contact and the second conductive contact corresponding thereto that have a maximum distance therebetween are taken as the first baseline row, the second column of first conductive contact and the second conductive contact corresponding thereto that have a maximum distance therebetween are taken as the second baseline row, the second column of first conductive contact and the second conductive contact corresponding thereto and the first column of first conductive contact and the second conductive contact corresponding thereto are respectively arranged on both sides adjacent to each of the first baseline row and the second baseline row to form the reference rows respectively. By controlling a distance between the conductive contacts in the reference rows, a space utilization in the first interconnection region 11 and the second interconnection region 20 is maximized, avoiding a short circuit and a parasitic capacitance between the conductive contacts.

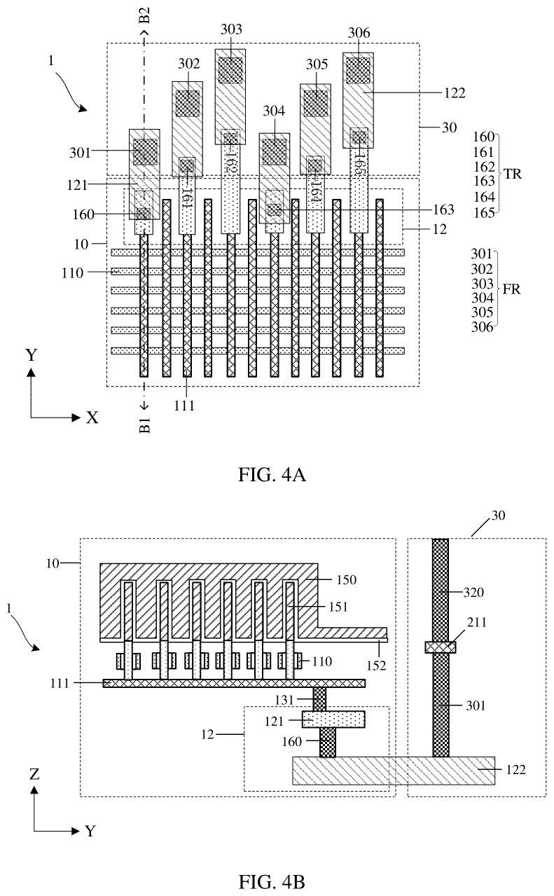

The semiconductor structure 1 provided in an embodiment of the present disclosure further includes multiple conductive contacts connected to columns of first bit lines 111 extending in the third direction Y. As shown in FIG. 4A and FIG. 4B, FIG. 4A is a simplified schematic plan view of the semiconductor structure 1 according to an embodiment of the present disclosure, and FIG. 4B is a cross-sectional view taken along a line B1-B2 in FIG. 4A. In the third direction Y, the semiconductor structure 1 further includes a third interconnection region 12, and the third interconnection region 12 includes multiple columns of first bit lines 111 that are isolated from each other and are parallel to each other in the third direction Y. A fourth interconnection region 30 is disposed adjacent to the first memory cell array 10 and the third interconnection region in the third direction Y, and the columns of bit lines in the first memory cell array 10 do not extend to the fourth interconnection region 30.

The third interconnection region 12 includes multiple second conductive lines 121 extending in the third direction Y, and the second conductive lines 121 are correspondingly disposed and connected to the first bit lines 111 in odd-numbered columns or even-numbered columns. The second conductive lines 121 extend in the third direction Y and are spaced apart in the first direction X, where some of the second conductive lines 121 extend in the third direction Y no further than the third interconnection region 12, and some of the second conductive lines 121 extend in the third direction Y from the third interconnection region 12 to the fourth interconnection region 30. The second conductive lines 121 and the first conductive lines 120 together may form a first layer of conductive lines of the semiconductor structure 1, which represents that the second conductive lines 121 and the first conductive lines 120 are conductive lines located in different regions and formed through the same conductive line manufacturing process.

With continued reference to FIG. 4A and FIG. 4B, the semiconductor structure 1 further includes a third conductive contact combination TR, and the third conductive contact combination TR includes multiple third conductive contacts, e.g., a third conductive contact 160 to a third conductive contact 165. Each of the third conductive contacts is provided in correspondence with each of the second conductive lines 121, some of the third conductive contacts are disposed in the third interconnection region 12, and some of the third conductive contacts are disposed in the fourth interconnection region 30, for example, the third conductive contact 160 and the third conductive contact 163 are disposed in the third interconnection region 12, and other third conductive contacts are disposed in the fourth interconnection region 30. A fourth conductive contact combination FR is further provided in the fourth interconnection region, and the fourth conductive contact combination FR includes multiple fourth conductive contacts, e.g., a fourth conductive contact 301 to a fourth conductive contact 306. Each of the fourth conductive contacts is provided in correspondence with and electrically connected to each of the third conductive contacts in the third direction Y.

With continued reference to FIG. 4A and FIG. 4B, a second conductive line 121 is connected to a first word line 111 corresponding thereto through a contact plug 131, and the third conductive contact 160 is directly in contact with and connected to the second conductive line 121. The fourth conductive contact 301 corresponding to the third conductive contact 160 extends in the second direction Z to a second contact pad 211 provided in correspondence with the fourth conductive contact 301. The second contact pad 211 is a conductive line disposed in the fourth interconnection region 30. The second contact pad 211 and the first contact pad 210 disposed in the second interconnection region 20 together may form the same layer of conductive lines of the semiconductor structure 1, which represents that the first contact pad 210 and the second contact pad 211 are connection pads located in different regions and formed through the same connection pad manufacturing process.

In some embodiments, the third interconnection region 12 is a region in which the ends of the first bit lines 111 in the third direction Y are located. A projection of each of the second conductive lines 121 and a projection of an end of a first bit line 111 corresponding thereto in the second direction Z have an overlapping region, a projection of each of the third conductive contacts and a projection of each of the second conductive lines 121 in the second direction Z also have an overlapping region, and the projection of the third conductive contact is located within the projection of the second conductive line 121.

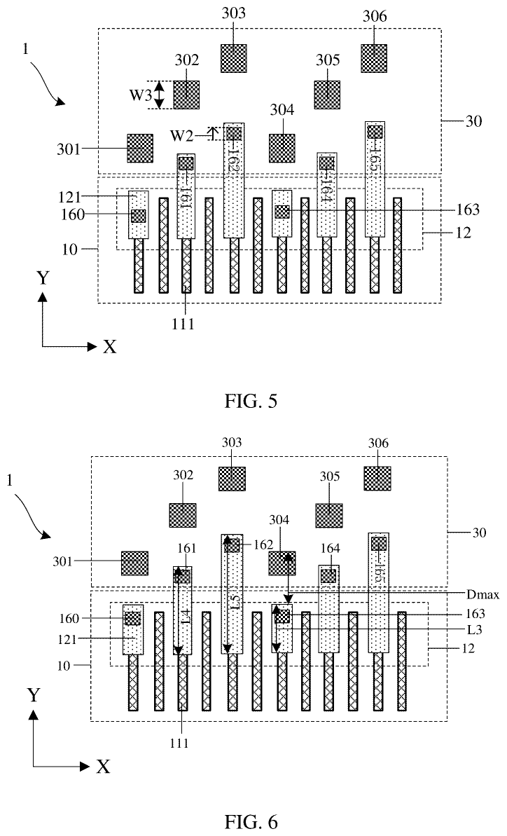

With continued reference to FIG. 5, FIG. 5 is a simplified schematic plan view of the semiconductor structure 1. The third conductive contacts in the semiconductor structure 1 have corresponding widths in the third direction Y, the widths of the third conductive contacts may be approximately the same or different, and the third conductive contacts have an average width, e.g., W2. The fourth conductive contacts also have corresponding widths in the third direction Y, and the widths of the fourth conductive contacts may be approximately the same or different. The fourth conductive contacts have an average width, e.g., W3, and the average width W2 of the third conductive contacts is less than the average width W3 of the fourth conductive contacts.

With continued reference to FIG. 6, FIG. 6 is a simplified schematic plan view of the semiconductor structure 1. In the third direction Y, each of the third conductive contacts is disposed adjacent to the same end portion of each of the second conductive lines 121. For example, the same end portion may be an end portion of each of the second conductive lines 121 being adjacent to the fourth interconnection region 30 or extending to the fourth interconnection region 30. In the third direction Y, there are distances between the third conductive contacts and the fourth conductive contacts corresponding thereto, and the distances are the same or substantially the same, e.g., a distance D8 between the third conductive contact 161 and the fourth conductive contact 302.

In some embodiments, the distances between the third conductive contacts and the fourth conductive contacts corresponding thereto may alternatively be partially the same or completely different, and the distances between the third conductive contacts and the fourth conductive contacts corresponding thereto in embodiments of the present disclosure are not limited thereto.

In the third direction Y, at least two second conductive lines 121 extending from the third interconnection region 12 to the fourth interconnection region 30 are provided between adjacent second conductive lines 121 in the third interconnection region 12. In the embodiment of the present disclosure, an example in which two second conductive lines 121 extending from the third interconnection region 12 to the fourth interconnection region 30 are provided between two adjacent second conductive lines 121 in the third interconnection region 12 is adopted for description. As shown in FIG. 6, the second conductive line 121 corresponding to the third conductive contact 163 is disposed in the third interconnection region 12, does not extend from the third interconnection region 12 to the fourth interconnection region 30, and has a length L3. Another third conductive contact adjacent to the third conductive contact and located in the third interconnection region 12 is the third conductive contact 160. The third conductive contact 161 and a third conductive contact 162 are further provided between the third conductive contact 160 and the third conductive contact 163. The length of the second conductive line 121 corresponding to the third conductive contact 161 in the third direction Y is L4, and the length of the second conductive line 121 corresponding to the third conductive contact 162 in the third direction Y is L5, and L4 is less than L5 and greater than L3.

In some embodiments, there is a maximum distance between each of the second conductive lines 121 disposed in the third interconnection region 12 and a fourth conductive contact corresponding thereto. For example, as shown in FIG. 6, a fourth contact pad 304 and a second conductive line 121 corresponding thereto are adopted as an example for description. A distance between an end edge of the second conductive line 121 corresponding to the third conductive contact 163 located in the third interconnection region 12 and an end edge that is of the fourth conductive contact 304 corresponding to the third conductive contact 163 and that is away from the third conductive contact 163 is a maximum distance Dmax, and a sum of Dmax and L3 is between L4 and L5.

In the above embodiment, the third conductive contacts have some arranged in the third interconnection region and some arranged in the fourth interconnection region, thereby effectively avoiding a short circuit between adjacent third conductive contacts or other adverse factors affecting electrical properties. In addition, a fourth interconnection region adjacent to the third interconnection region is provided outside the third interconnection region, and a predetermined distance is maintained between a fourth conductive contact in the fourth interconnection region and a third conductive contact, so as to maximize a space utilization between the third interconnection region and the fourth interconnection region, and avoid a short circuit and a parasitic capacitance between the conductive contacts, which provides a design idea and practice for further increasing device density or wiring density, and further improves a degree of integration of the semiconductor structure.

In some embodiments, a quantity of rows of the first word lines in the first memory cell array 10 is less than a quantity of columns of the first bit lines. For example, the first memory cell array 10 includes 512 rows of first word lines and 1024 columns of first bit lines.

With continued reference to FIG. 1A, FIG. 1B, FIG. 4A, and FIG. 4B, the semiconductor structure 1 further includes multiple third conductive lines 122, including some of the third conductive lines 122 disposed in the first interconnection region 11 and the second interconnection region 20, and some of the third conductive lines 122 disposed in the third interconnection region 12 and the fourth interconnection region 30, where the third conductive lines 122 disposed in the first interconnection region 11 are provided in correspondence with and connected to the first conductive contacts respectively, and the third conductive lines 122 disposed in the second interconnection region 20 are provided in correspondence with and connected to the second conductive contacts respectively. The third conductive lines 122 disposed in the third interconnection region 12 and the fourth interconnection region 30 separately extend from the third interconnection region 12 to the fourth interconnection region 30. In addition, each of the third conductive lines 122 is connected to a third conductive contact and a fourth conductive contact that are corresponding thereto, that is, each of the third conductive contacts and each of the fourth conductive contacts corresponding thereto are interconnected via each of the third conductive lines 122 extending in the third interconnection region 12 and the fourth interconnection region 30.

In some embodiments, each of the third conductive lines 122 located in the first interconnection region 11 has the same or approximately the same width in the first direction X, a projection area of each of the third conductive lines 122 in the first interconnection region 11 in the second direction Z is greater than a projection area of each of the corresponding first conductive contacts, and the projection of each of the first conductive contacts is located within the projection of each of the third conductive lines 122.

In some embodiments, each of the third conductive lines 122 located in the second interconnection region 20 has the same or approximately the same width in the first direction X, a projection area of each of the third conductive lines 122 in the first interconnection region 11 in the second direction Z is greater than a projection area of each of the corresponding second conductive contacts, and the projection of each of the second conductive contacts is located within the projection of each of the third conductive lines 122.

In some embodiments, a dimension of each of the third conductive lines 122 located in the first interconnection region 11 may be the same as or different from a dimension of each of the third conductive lines 122 located in the second interconnection region 20. FIG. 1A and FIG. 1B illustrate that the dimension of each of the third conductive lines 122 located in the first interconnection region 12 is different from the dimension of each of the third conductive lines 122 located in the second interconnection region 20.

In some embodiments, each of the third conductive lines 122 corresponding to each of the third conductive contacts and each of the fourth conductive contacts has the same or approximately the same extension length in the third direction Y; and in the second direction Z, a projection of each of the third conductive contacts and a projection of each of the fourth conductive contacts are located within a projection of a corresponding third conductive line 122.

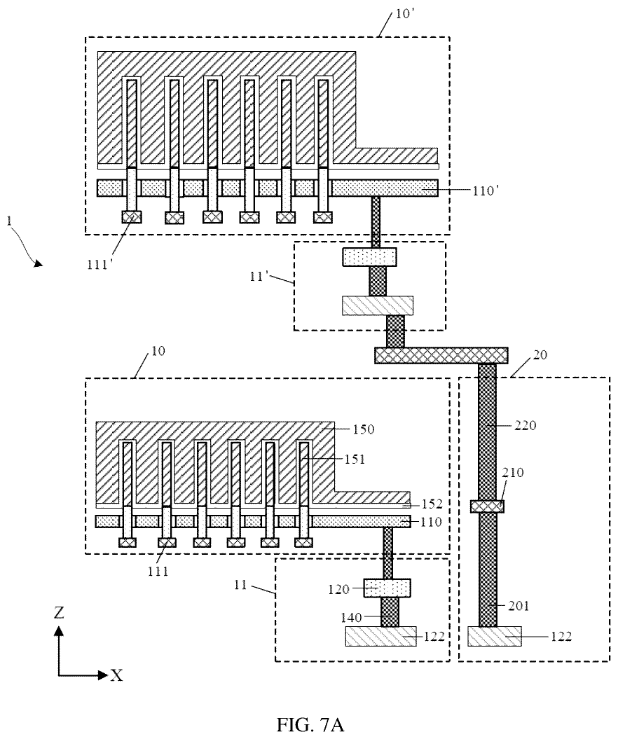

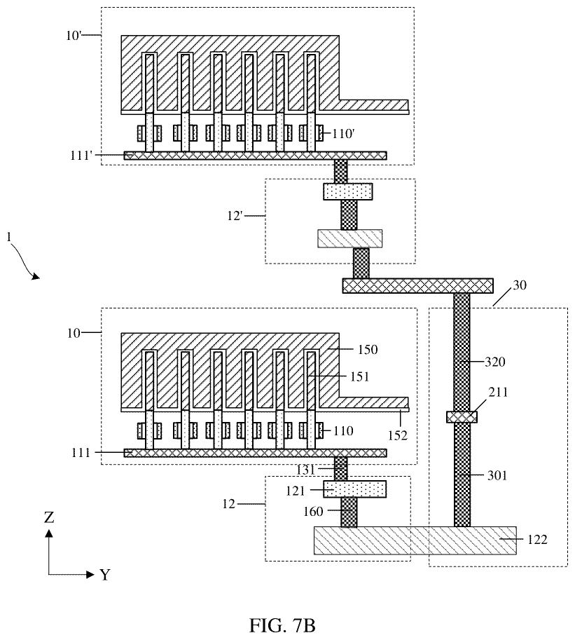

With continued reference to FIG. 7A and FIG. 7B, FIG. 7A is a cross-sectional view of the semiconductor structure 1 along a section parallel to the second direction Z according to an embodiment of the present disclosure, and FIG. 7B is a cross-sectional view of the semiconductor structure 1 along a section parallel to the second direction Z. The semiconductor structure 1 further includes a second memory cell array 10′, and the second memory cell array 10′ has a structure similar to that of the first memory cell array 10. For example, the second memory cell array 10′ includes multiple rows of second word lines 110′ arranged in parallel in the first direction X and multiple rows of second bit lines 111′ arranged in parallel in the third direction Y.

With continued reference to FIG. 7A, in some embodiments, an interconnection region 11′ is further provided below the second word line 110′, and the interconnection region 11′ is connected to the second word lines 110′ in odd-numbered or even-numbered rows in the second memory cell array 10′; and an interconnection channel connected to the corresponding first word lines 110 in the first memory cell array 10 is formed between the interconnection region 11′ and the second interconnection region 20, e.g., a connection channel formed by connecting the first contact pad 210 of the second conductive contact 201 and the contact plug 220, so that a connection channel of each of the second word lines 110′ in the second memory cell array 10′ is formed in the second interconnection region 20.

With continued reference to FIG. 7B, in some embodiments, an interconnection region 12′ is further provided below the second memory cell array 10′, and the interconnection region 12′ is connected to the second bit lines 111′ in odd-numbered or even-numbered columns in the second memory cell array 10′; and an interconnection channel connected to the corresponding first bit lines 111 in the first memory cell array 10 is formed between the interconnection region 12′ and the second interconnection region 30, e.g., a connection channel formed by connecting the second contact pad 211 of the fourth conductive contact 301 and the contact plug 320, so as to achieve interconnection between the first bit line 111 and the second bit line 110′.

In some embodiments, the first contact pad 210 and the second contact pad 211 may be formed in the same process technology. In some embodiments, the first contact pad 210 and the second contact pad 211 are located between the capacitor array and the first word line 110, and top surfaces of the second interconnection region 20 and the fourth interconnection region 30 are higher than a top surface of the capacitor array. By providing the first contact pad 210 and the second contact pad 211, it is possible to prevent each of the second conductive contacts and each of the fourth conductive contacts from extending a long length in the second interconnection region 20 or the fourth interconnection region 30, thereby further reducing process difficulty. In some other embodiments, the second interconnection region 20 and the fourth interconnection region 30 may alternatively be provided with the second conductive contacts and the fourth conductive contacts extending in the second direction Z.

In some embodiments, there is a bonding surface formed through a direct bonding or hybrid bonding process between the first memory cell array 10 and the second storage unit array 10′, and a connection relationship between the word lines and the bit lines in the first memory cell array 10 and the second memory cell array 10′ is achieved through the bonding surface.

In some embodiments, the semiconductor structure 1 further includes a logic cell array (not shown in the figure). The logic cell array includes a portion connected to the third conductive lines 122 in the first interconnection region 11, a portion connected to the third conductive lines 122 in the second interconnection region 20, and a portion connected to the third conductive lines 122 in the third interconnection region 12 and the fourth interconnection region 30, so as to achieve corresponding operations on the first word lines 110 and the first bit lines 111 in the first memory cell array 10 and the second word lines 110′ and the second bit lines 111′ in the second memory cell array 10′.

In the above embodiment, the first memory cell array 10 and the second memory cell array 10′ may be a memory cell array including a DRAM memory cell, a NAND memory cell, or another memory cell, and a logical cell array may be of any suitable digital, analog, and/or hybrid signal circuit structure configured to facilitate operation of a memory structure.

A person of ordinary skill in the art may understand that the above implementations are specific embodiments for implementing the present disclosure. In an actual application, various modifications may be made to the forms and details of the implementations without departing from the spirit and scope of the embodiments of the present disclosure. Any person skilled in the art may make changes and modifications without departing from the spirit and scope of the embodiments of the present disclosure. Therefore, the protection scope of the embodiments of the present disclosure shall be subject to the scope defined by the claims.

What is claimed is:

1. A semiconductor structure, comprising:
a first memory cell array, the first memory cell array comprising a plurality of rows of first word lines extending in a first direction, and the
first word lines being isolated from each other;
a first interconnection region comprising a plurality of first conductive lines extending in the first direction, each of the first conductive lines being provided in correspondence with and connected to
each of the first word lines in odd-numbered rows or even-numbered rows;
a first conductive contact combination, the first conductive contact combination being disposed in the first interconnection region, the first conductive contact
combination comprising a plurality of first conductive contacts, each of the first conductive contacts being provided in correspondence with each of the first conductive lines, and each of the first conductive contacts extending in a second direction and being connected to each of the first conductive lines; and
a second interconnection region, the second interconnection region being disposed adjacent to the first memory cell array and the first interconnection region in the first direction, a second conductive contact combination being provided in the second interconnection region, the second conductive contact combination comprising a plurality of second conductive contacts, and each of the second conductive contacts being provided in correspondence with and isolated from each of the first conductive contacts; and
a plurality of first contact pads being provided in the second interconnection region, each of the second conductive contacts extending in the second direction and being connected to each of the first contact pads, wherein there is a minimum distance D0 between adjacent first conductive contacts in the first direction, there is a minimum distance D1 between adjacent second conductive contacts in the first direction, and the minimum distance D0 is less than the minimum distance D1; and in the second direction, each of the first conductive contacts has a minimum length L0, each of the second conductive contacts has a minimum length L1, and the minimum length L0 is less than the minimum length L1.

2. The semiconductor structure according to claim 1, wherein in the first direction, the first conductive contacts in the first conductive contact combination have an average width W0, the second conductive contacts in the second conductive contact combination have an average width W1, and the average width W0 of the first conductive contacts is less than the average width W1 of the second conductive contacts.

3. The semiconductor structure according to claim 1, wherein the first conductive contact combination comprises a first column of first conductive contact combination and a second column of first conductive contact combination that are spaced apart in a third direction, the first conductive contacts in the first column of first conductive contact combination are respectively connected to the first conductive lines in odd-numbered rows, and the first conductive contacts in the second column of first conductive contact combination are respectively connected to the first conductive lines in even-numbered rows; in the first direction, at least one first conductive contact in the first column of first conductive contact combination and a corresponding second conductive contact in the second conductive contact combination have a maximum distance D2 therebetween; and a first conductive contact and a second conductive contact that have the maximum distance D2 therebetween form a first baseline row, and a maximum distance between each of the first conductive contacts in the second column of first conductive contact combination disposed adjacent to the first baseline row and each of the second conductive contacts provided corresponding thereto is less than the maximum distance D2.

4. The semiconductor structure according to claim 3, wherein the first conductive contacts and the second conductive contacts that are disposed adjacent to the first baseline row form a first reference row and a second reference row respectively; there is a maximum distance D3 between a first conductive contact and a second conductive contact in the first reference row, and there is a maximum distance D4 between a first conductive contact and a second conductive contact in the second reference row; and the maximum distance D3 is greater than the maximum distance D4, and both the maximum distance D3 and the maximum distance D4 are less than the maximum distance D2.

5. The semiconductor structure according to claim 3, wherein in the first direction, at least one first conductive contact in the second column of first conductive contact combination and a corresponding second conductive contact in the second conductive contact combination have a maximum distance D5 therebetween; and a first conductive contact and a second conductive contact that have the maximum distance D5 therebetween form a second baseline row, and a maximum distance between each of the first conductive contacts in the first column of first conductive contact combination disposed adjacent to the second baseline row and each of the second conductive contacts provided corresponding thereto is less than the maximum distance D5.

6. The semiconductor structure according to claim 5, wherein the first conductive contacts and the second conductive contacts that are disposed adjacent to the second baseline row form a third reference row and a fourth reference row respectively; there is a maximum distance D6 between a first conductive contact and a second conductive contact in the third reference row, and there is a maximum distance D7 between a first conductive contact and a second conductive contact in the fourth reference row; and the maximum distance D6 is greater than the maximum distance D7, and both the maximum distance D6 and the maximum distance D7 are less than the maximum distance D5.

7. The semiconductor structure according to claim 1, wherein the first memory cell array further comprises:
a plurality of columns of first bit lines extending in a third direction, the first bit lines being isolated from each other;
a third interconnection region, the third interconnection region comprising a plurality of second conductive lines extending in the third direction, and each of
the second conductive lines being provided in correspondence with and connected to each of the first bit lines in odd-numbered columns or even-numbered columns;
a fourth interconnection region, the fourth interconnection region being disposed adjacent to the first memory cell array and the third interconnection region in the third direction, some of the second conductive lines being disposed in the third interconnection region, and some of the second conductive lines extending from the third interconnection region to the fourth interconnection region; and
a third conductive contact combination, the third conductive contact combination comprising a plurality of third conductive contacts, the third conductive contacts comprising a plurality of third conductive contacts disposed in the third interconnection region and a plurality of third conductive contacts disposed in the fourth interconnection region, and each of the third conductive contacts being correspondingly connected to each of the first conductive lines; and
a fourth conductive contact combination being provided in the third interconnection region, the fourth conductive contact combination comprising a plurality of fourth conductive contacts, and each of the fourth conductive contacts being provided in correspondence with and connected to each of the third conductive contacts.

8. The semiconductor structure according to claim 7, wherein in the third direction, the third conductive contacts in the third conductive contact combination have an average width W2, the fourth conductive contacts in the fourth conductive contact combination have an average width W3, and the average width W2 of the third conductive contacts is less than the average width W3 of the fourth conductive contacts.

9. The semiconductor structure according to claim 7, wherein in the third direction Y, distances between the third conductive contacts and the fourth conductive contacts corresponding thereto are the same.

10. The semiconductor structure according to claim 7, wherein in the third direction, each of the second conductive lines located in the third interconnection region has a length L3; there are at least two second conductive lines extending to the fourth interconnection region between adjacent second conductive lines in the third interconnection region, and the second conductive lines extending to the fourth interconnection region have different lengths greater than the length L3; there is a maximum distance Dmax between each of the second conductive lines located in the third interconnection region and each of the fourth conductive contacts disposed corresponding thereto; and a sum of the maximum distance Dmax and the length L3 is between length values of the second conductive lines extending to the fourth interconnection region.

11. The semiconductor structure according to claim 7, wherein a quantity of rows of the first word lines in the first memory cell array is less than a quantity of columns of the first bit lines in the third interconnection region.

12. The semiconductor structure according to claim 7, further comprising a plurality of third conductive lines, the plurality of third conductive lines comprising some disposed in the first interconnection region and the second interconnection region and some disposed in the third interconnection region and the fourth interconnection region, the third conductive lines disposed in the first interconnection region and the second interconnection region being correspondingly connected to the first conductive contacts and the second conductive contacts respectively, and the third conductive lines disposed in the third interconnection region and the fourth interconnection region being correspondingly connected to the third conductive contacts and the fourth conductive contacts respectively.

13. The semiconductor structure according to claim 1, further comprising a second memory cell array, the second memory cell array comprising a plurality of rows of second word lines extending in the first direction and being isolated from each other, and each of the second word lines being correspondingly connected to each of the second conductive contacts.

14. The semiconductor structure according to claim 7, further comprising a second memory cell array, the second memory cell array comprising a plurality of rows of second bit lines extending in the third direction and being isolated from each other, and each of the second bit lines being correspondingly connected to each of the fourth conductive contacts.
